(19) United States
(12) Patent Application Publication
(10) Pub. No.: US 2007/0045658 A1
(43) Pub. Date: Mar. 1, 2007

(54) SYSTEM AND METHOD TO PROVIDE POWER TO A MOTOR

(75) Inventor: Chadi Shaya, Sterling Heights, MI (US)

Correspondence Address: BROOKS KUSHMAN P.C. / LEAR CORPORATION, 1000 TOWN CENTER, TWENTY-SECOND FLOOR, SOUTHFIELD, MI, 48075-1238, US

(73) Assignee: LEAR CORPORATION, Southfield, MI (US)

(21) Appl. No.: 11/162,211

(22) Filed: Sep. 1, 2005

(51) Int. Cl. H01L 29/74

(52) U.S. Cl. 257/146

(57) ABSTRACT

A system to provide power to a motor includes a multi-channel output array comprising first and second field effect transistors configured to be operable simultaneously.

### BACKGROUND OF THE INVENTION

1. Field of the Invention

The invention relates to a system and method to provide power to a motor.

2. Background Art

Field Effect Transistors (FETs) can be used as a switch to allow high current to pass from a power source to a motor. A typical configuration using FETs to drive a motor requires the simultaneous activation of two FETs: a high-side FET and a low-side FET. Packaging considerations, however, may limit the amount of space available for the FETs. For example, the available space may be insufficient to package two separate FETs. Therefore, a need exists for a multi-channel output array that can provide two FETs that can be activated simultaneously.

### SUMMARY OF THE INVENTION

An object of the invention is to provide a multi-channel output array with two Field Effect Transistors that can be activated simultaneously.

An object of the invention is to provide power to a motor using a multi-channel output array.

An object of the invention is to provide a system utilzing a multi-channel output array to provide power to a motor that can also determine information about the operation of the motor.

### BRIEF DESCRIPTION OF THE DRAWINGS

FIG. 1 is a schematic representation of an embodiment of a multi-channel output array;

FIG. 2 is a block diagram of a circuit integrated with the multi-channel output array of FIG. 1;

FIG. 3 is a block diagram of a system configured to provide power to several motors; and

FIG. 4 is a flow chart of a method associated with the system of FIG. 3.

### DETAILED DESCRIPTION OF THE PREFERRED EMBODIMENT(S)

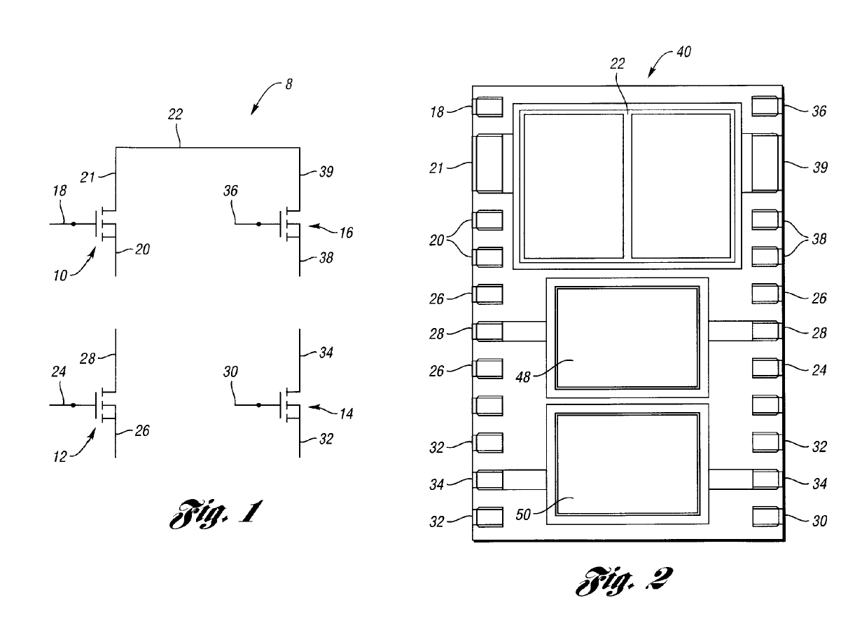

FIG. 1 shows a schematic representation of an embodiment of a multi-channel output array 8. A first field effect transistor (FET) 10, a second FET 12, a third FET 14 and a fourth FET 16 are shown. Although the embodiment of a multi-channel output array 8 of FIG. 1 is shown with four FETs, a fewer number of FETs or a greater number of FETs may be used as desired. The first FET 10 has a gate 18, a source 20, and a drain 21. Drain 21 is electrically connected to heat slug 22. The second FET 12 has a gate 24, a source 26, and a drain 28. The third FET 14 has a gate 30, a source 32, and a drain 34. The fourth FET 16 has a gate 36, a source 38, and a drain 39. Drain 39 shares the heat slug 22 with drain 21 of the first FET 10.

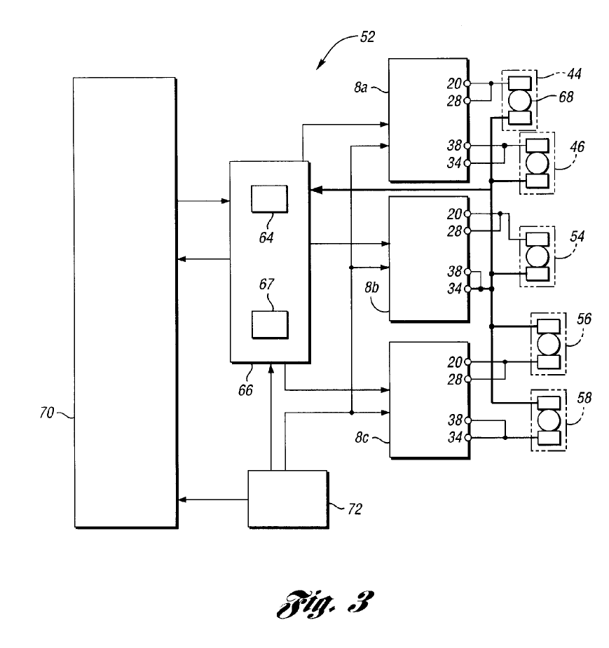

FIG. 2 shows the pads of an integrated circuit (IC) 40 associated with gate 18, source 20, and drain 21 of FET 10; gate 24, source 26, and drain 28 of FET 12; gate 30, source 32, and drain 34 of FET 14; and gate 36, source 38, and drain 39 of FET 16. The pads facilitate the electrical connections between the FETs 10, 12, 14, and 16 of the multi-channel output array 8 and other components. The FETs 10, 12, 14, and 16 are integrated in a manner consistent with the art and may be located on the IC 40 as desired. The FETs 10, 12, 14, and 16 of the embodiment of FIG. 2 are 6.8 mOhm, n-type MOSFETS but other types, such as lower on-resistance FETs, e.g., 2.0 mOhm, may be used as desired. The relatively low resistance of FETs 10, 12, 14, and 16 allows each to pass a relatively high current, e.g., 8 amps at 18 volts.

Because of their relatively low resistance, FETs 10, 16 can generate heat that may be difficult to dissipate when passing a current. As a result, FETs 10, 16 share the common heat slug 22 to improve the amount of heat each can dissipate when activated. The IC 40 does not provide common circuitry to protect against failures, such as over-voltage and over-temperature diagnostic control. Therefore, the IC 40 provides increased area for the heat slug 22 to occupy. The heat slug 22 associated with drains 21, 39 has roughly twice the area of heat slugs 48, 50 associated with drains 28, 34 respectively. The area provided by heat slug 22 effectively dissipates the heat generated by FETs 10, 16 when respectively activated.

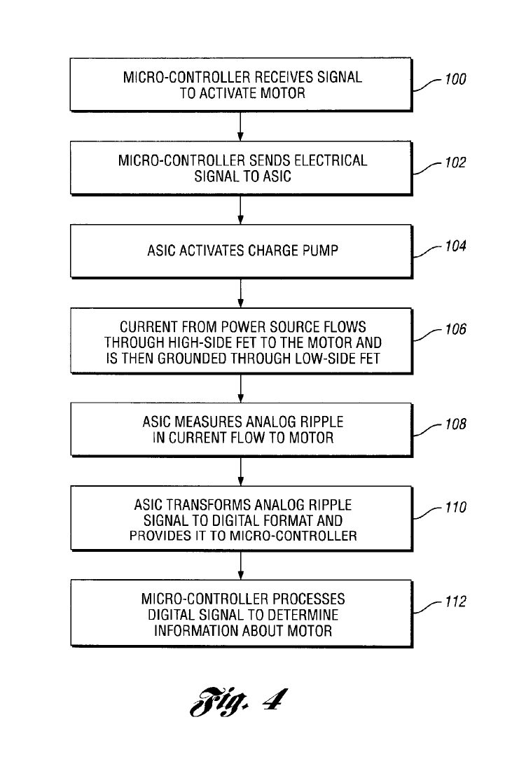

FIG. 3 shows an embodiment of a system 52 to provide power to motors 44, 46, 54, 56, and 58 using three multi-channel output arrays 8a-8c. FETs 10, 16 of multi-channel output arrays 8a-8c are configured as independent high-sides, i.e., gates 18, 36 are configured to be activated independently. FETs 12, 14 of multi-channel output arrays 8a-8c are configured as independent low-sides. The FETs 10, 12, 14, and 16 are electrically connected in a typical H-Bridge configuration, e.g., FET 10 of multi-channel output array 8a and FET 14 of multi-channel output array 8b can drive the motor 44 in one direction while FET 16 of multi-channel 8b and FET 12 of multi-channel output array 8a can drive the motor 44 in the opposite direction. In contrast to existing systems, however, multi-channel output arrays 8a-8c each have a set of FETs 10, 12, 14, and 16, integrated on a respective IC 40 and are configured such that the heat generated by two FETs activated simultaneously, e.g., FETs 10, 14 of multi-channel output array 8b, can be dissipated effectively.

In the system 52, a charge pump 64 resides on an application specific integrated circuit (ASIC) 66. The charge pump 64 is electrically connected to each of the pads associated with gates 18 of FET 10, gate 24 of FET 12, gate 30 of FET 14, and gate 36 of FET 16 (FIG. 2) in a manner consistent with the art for each multi-channel output array 8a-8c. In existing systems, a charge pump is integrated with an FET and is responsible for turning on the gate using a capacitive charging method. The charge pump circuitry, however, occupies board space and is not included in the multi-channel output arrays 8a-8c because it would (1) require a larger package size for each multi-channel output array, and (2) reduce the area available, for example, for heat slug 22 to occupy. Because the ASIC 66 is an optional component of the system 52, the charge pump 64 can reside elsewhere in the system 52. For example, the charge pump 64 may reside on its own discrete circuit.

The ASIC 66 can be further configured to receive electrical signals from the motors 44, 46, 54, 56, and 58 by reading a respective motor current. By providing pull downs 67, e.g., resistors connected to ground, which may be external or internal to the ASIC 66, the ASIC 66 is able to read and translate these respective currents into analog voltages in a manner consistent with the art. These analog voltages contain information about the operation of the motors 44, 46, 54, 56, and 58. For example, in the system 52, where motor 44 is typically a DC brush motor, each time the brush (not shown) of the motor 44 passes over an etch (not shown) of the motor 44's commutator 68, a disturbance in a current flow to the motor 44 can be measured via the pull downs 67. In other words, every time the brush shifts between a different pole of the commutator 68, there is an increase, or ripple, in the current. The brush of motor 44 encounters an etch at regular intervals, for example, every 36 degrees, on the commutator 68. A ripple in the current flow to the motor 44 can thus contain information about the translation or rotation of a component, such as a seat, moved by the motor 44.

The ASIC 66 can further be configured in a standard fashion to convert, for example, the analog electrical signal from motor 44 into a digital signal and to provide this digital signal to a micro controller 70 which is electrically connected to the ASIC 66 in a manner consistent with the art. The micro controller 70 can be configured to read the ripple in the current via the digital signal provided by the ASIC 66 and determine position, for example, by using a look-up table. The micro controller 70 can thus process the digital signals to determine a position of a component, such as a seat, driven by the motor 44.

FIG. 4 shows a method associated with system 52. When the micro controller 70 receives a signal to activate motor 54, (block 100), the micro controller 70 sends an electrical signal to the ASIC 66 (block 102). The ASIC 66 activates the charge pump 64 that, in turn, activates gate 18 of FET 10 and gate 30 of FET 14, both of multi-channel output array 8b (block 104). With gates 18, 30 activated, a current from the power source 72 flows from the drain 21, which is electrically connected to the power source 72 via the pad associated with drain 21 (FIG. 2) in a manner consistent with the art, to the source 20 of FET 10. The current then flows from the source 20 of FET 10, via the pads associated with source 20 (FIG. 2), to the motor 54. The current is then grounded through FET 14 via the pads associated with drain 34 of multi-channel output array 8b (block 106). While the current from the power source 72 is flowing to the motor 54, the ASIC 66 measures, via the pull downs 67, the ripple in the current flow to the motor 54 (block 108). The ASIC 66 then transforms these analog signals to a digital format and provides them to the micro controller 70 (block 110). The micro controller 70 processes these digital signals in a manner consistent with the art to determine information about the operation of the motor 54 (block 112).

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A system for providing power to a motor, the system comprising:
a multi-channel output array comprising first and second field effect transistors configured to be operable simultaneously, the multi-channel output array being electrically connected to the motor.

2. The system of claim 1 further comprising a micro controller electrically connected to the multi-channel output array, the micro controller configured to process a signal, the signal containing information concerning the operation of the motor.

3. The system of claim 1 further comprising a charge pump external to the multi-channel output array, the charge pump configured to provide power to activate the first and second field effect transistors.

4. The system of claim 3 wherein the multi-channel output array further comprises a third field effect transistor.

5. The system of claim 4 wherein the third field effect transistor and the first field effect transistor share a common drain.

6. The system of claim 5 wherein the third field effect transistor and the first field effect transistor share a common thermally conductive material capable of dissipating heat.

7. The system of claim 3 further comprising a device external to the multi-channel output array, the device configured to monitor the current passing from the multi-channel output array to the motor.

8. A method of providing power to a motor, the method comprising:
using a current provided by a first device external to a multi-channel output array to concurrently activate a first and second field effect transistor of the multi-channel output array; and,
passing a current provided by a second device to the motor through the multi-channel output array.

9. The method of claim 8 furthering comprising monitoring the current passing from the multi-channel output array through the motor.

10. The method of claim 9 further comprising processing a signal containing information concerning the operation of the motor.

11. The method of claim 10 further comprising determining the cycles of rotation of a component of the motor.
